(19) United States
(12) Patent Application Publication
(10) Pub. No.: US 2026/0101623 A1
(43) Pub. Date: Apr. 9, 2026

(54) CERAMIC SINTERED BODY SUBSTRATE, LIGHT-EMITTING DEVICE, AND METHODS FOR MANUFACTURING CERAMIC SINTERED BODY SUBSTRATE AND LIGHT-EMITTING DEVICE

(71) Applicant: NICHIA CORPORATION, Anan-shi (JP)

(72) Inventors: Masaaki KATSUMATA, Anan-shi (JP); Akiko NAGAE, Tokushima-shi (JP); Eiko MINATO, Anan-shi (JP)

(73) Assignee: NICHIA CORPORATION, Anan-shi (JP)

(21) Appl. No.: 19/112,215

(22) PCT Filed: Sep. 14, 2023
(86) PCT No.: PCT/JP2023/033612

§ 371 Date: Mar. 14, 2025

(30) Foreign Application Priority Data
Sep. 16, 2022 (JP) 2022-148504

(51) Int. Cl. H10H 29/85; H10H 29/01; H10H 29/24

(52) U.S. Cl. CPC H10H 29/8508; H10H 29/036; H10H 29/0364; H10H 29/24; H10H 29/857

(57) ABSTRACT

A method for manufacturing a ceramic sintered body substrate includes preparing a ceramic substrate 1 provided with a through hole 2 before firing (S11), disposing a first metal paste 3 in the through hole (S12), and firing the ceramic substrate provided with the first metal paste (S14). In the disposing of the first metal paste, the first metal paste includes a plurality of particles of first metal powder (4) and a plurality of particles of active metal powder (50), and the first metal powder includes a metal powder (4a) serving as a core, and a covering metal member (40b) having a melting point lower than a melting point of the metal powder and covering at least a part of the metal powder, and in the firing of the ceramic substrate, a firing temperature is a temperature in a range from 700° C. to less than the melting point of the metal powder.

### TECHNICAL FIELD

The present disclosure relates to a ceramic sintered body substrate, a light-emitting device, and methods for manufacturing the ceramic sintered body substrate and the light-emitting device.

### BACKGROUND ART

In the related art, a via material used for a ceramic substrate includes a through conductor containing silver and copper as main components, and the through conductor is known to include a eutectic region of silver and copper in a metal layer side region in a center region of a diameter and a non-eutectic region of silver and copper in a central region in the center region of the diameter. As the via material used for the ceramic substrate, a via material is known which is obtained by being filled with a first metal paste containing a powder of a metal B having a higher melting point than a metal A having a melting point in a range from 600° C. to 1100° C. and an active metal, and layering a second metal paste containing a powder of the metal A at a position in contact with the first metal paste (for example, see Patent Documents 1 and 2).

### CITATION LIST

### Patent Literature

Patent Document 1: JP 6122561 B
Patent Document 2: JP 5922739 B

### SUMMARY OF INVENTION

### Technical Problem

An object of an embodiment according to the present disclosure is to provide a ceramic sintered body substrate having high reliability, a light-emitting device, and methods for manufacturing the ceramic sintered body substrate and the light-emitting device.

### Solution to Problem

A method for manufacturing a ceramic sintered body substrate disclosed in an embodiment includes preparing a ceramic substrate provided with a through hole before firing; disposing a first metal paste in the through hole; and firing the ceramic substrate provided with the first metal paste, wherein in the disposing of the first metal paste, the first metal paste includes a plurality of particles of first metal powder and a plurality of particles of active metal powder, and the first metal powder includes a metal powder serving as a core, and a covering metal member having a melting point lower than a melting point of the metal powder and covering at least a part of the metal powder, and in the firing of the ceramic substrate, a firing temperature is a temperature in a range from 700° C. to less than the melting point of the metal powder.

A method for manufacturing a light-emitting device disclosed in an embodiment includes preparing a ceramic sintered body substrate manufactured by the above-described method for manufacturing a ceramic sintered body substrate; and disposing a light-emitting element on the ceramic sintered body substrate, wherein in the preparing of the ceramic sintered body substrate, the first metal paste becomes a first metal body by firing, and in the disposing of the light-emitting element, the first metal body disposed in the through hole is directly or indirectly electrically connected to the light-emitting element.

A method for manufacturing a light-emitting device disclosed in an embodiment includes preparing a ceramic sintered body substrate manufactured by the above-described method for manufacturing a ceramic sintered body substrate; and disposing a light-emitting element on the ceramic sintered body substrate, wherein in the preparing of the ceramic sintered body substrate, the first metal paste becomes a first metal body and the conductive paste becomes a conductor by firing, and in the disposing of the light-emitting element, the first metal body disposed in the through hole or the conductor is directly or indirectly electrically connected to the light-emitting element.

A ceramic sintered body substrate disclosed in an embodiment includes a ceramic substrate provided with a through hole; and a first metal body disposed in the through hole, wherein the first metal body includes a plurality of particles of metal powder, a second metal, and a metal compound, the metal powder having a melting point higher than a melting point of the second metal and being dispersed in the second metal that is continuous, and the ceramic substrate includes a reaction layer of the metal compound on an inner wall of the through hole, and a reactant of the metal compound on a grain boundary of the metal powder.

A light-emitting device disclosed in an embodiment includes the above-described ceramic sintered body substrate; and a light-emitting element electrically connected to the first metal body of the ceramic sintered body substrate.

### Advantageous Effects of Invention

An embodiment of the present disclosure can provide a ceramic sintered body substrate having high reliability, a light-emitting device, and methods for manufacturing the ceramic sintered body substrate and the light-emitting device.

### BRIEF DESCRIPTION OF DRAWINGS

FIG. 1 is a plan view schematically illustrating a ceramic sintered body substrate according to an embodiment.

FIG. 2 is a cross-sectional perspective view schematically illustrating a cross section taken along line II-II of FIG. 1.

FIG. 3A is an enlarged cross-sectional view schematically illustrating a state in which a first metal paste is disposed in a through hole of the ceramic sintered body substrate according to the embodiment.

FIG. 3B is an enlarged cross-sectional view schematically illustrating a state of a first metal body after the ceramic sintered body substrate in FIG. 3A is sintered.

FIG. 4A is an enlarged scanning electron microscope image showing the first metal body disposed in the through hole of the ceramic sintered body substrate according to the embodiment.

FIG. 4B is an enlarged scanning electron microscope image showing the first metal body disposed in the through hole of the ceramic sintered body substrate according to the embodiment.

FIG. 5 is a flowchart exemplifying a method for manufacturing the ceramic sintered body substrate according to the embodiment.

FIG. 6A is a cross-sectional view schematically illustrating a prepared ceramic substrate in the method for manufacturing the ceramic sintered body substrate according to the embodiment.

FIG. 6B is a cross-sectional view schematically illustrating a state in which a first metal paste is disposed in a through hole in the method for manufacturing the ceramic sintered body substrate according to the embodiment.

FIG. 6C is a cross-sectional view schematically illustrating a state in which a conductive paste is disposed in the method for manufacturing the ceramic sintered body substrate according to the embodiment.

FIG. 7 is a cross-sectional view schematically illustrating a light-emitting device according to the embodiment.

FIG. 8 is a flowchart exemplifying a method for manufacturing the light-emitting device according to the embodiment.

FIG. 9A is a cross-sectional view schematically illustrating a prepared ceramic sintered body substrate in the method for manufacturing the light-emitting device according to the embodiment.

FIG. 9B is a cross-sectional view schematically illustrating a state in which a bonding member is disposed on the ceramic sintered body substrate in the method for manufacturing the light-emitting device according to the embodiment.

FIG. 9C is a cross-sectional view schematically illustrating a state in which a light-emitting element is disposed in the method for manufacturing the light-emitting device according to the embodiment.

FIG. 9D is a cross-sectional view schematically illustrating a state in which a light reflective member is disposed in the method for manufacturing the light-emitting device according to the embodiment.

FIG. 10A is a perspective view illustrating the light-emitting device according to the embodiment as a light-emitting module.

FIG. 10B is a cross-sectional view schematically illustrating a cross section taken along line XB-XB with a part of FIG. 10A omitted.

### DESCRIPTION OF EMBODIMENTS

Embodiments according to the present disclosure are described below with reference to the drawings. However, the embodiments described below are merely intended to embody the technical concept according to the present disclosure, and the invention is not limited to the following description unless otherwise specified. The contents described in one embodiment can also be applied to another embodiment or a modified example. The drawings are diagrams that schematically illustrate the embodiments. To provide clarity in the description, scales, intervals, positional relationships, and the like of members may be exaggerated, or some of the members may be omitted in the drawings. Directions illustrated in the drawings indicate relative positions between constitution components and are not intended to indicate absolute positions. Note that members having the same names and reference signs, as a rule, represent the same or similar members, and detailed description thereof is omitted as appropriate. In the embodiments, “covering” includes not only a case of covering by direct contact but also a case of indirectly covering, for example, via another member.

### Ceramic Sintered Body Substrate

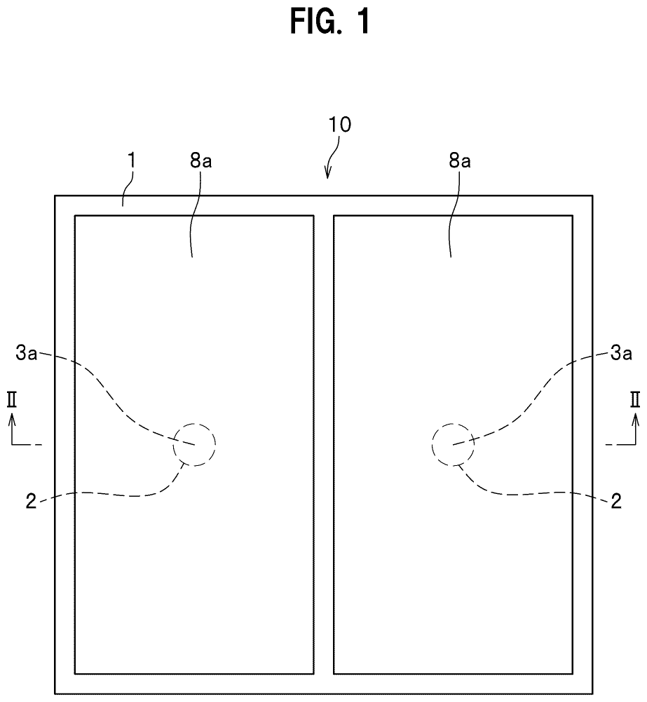

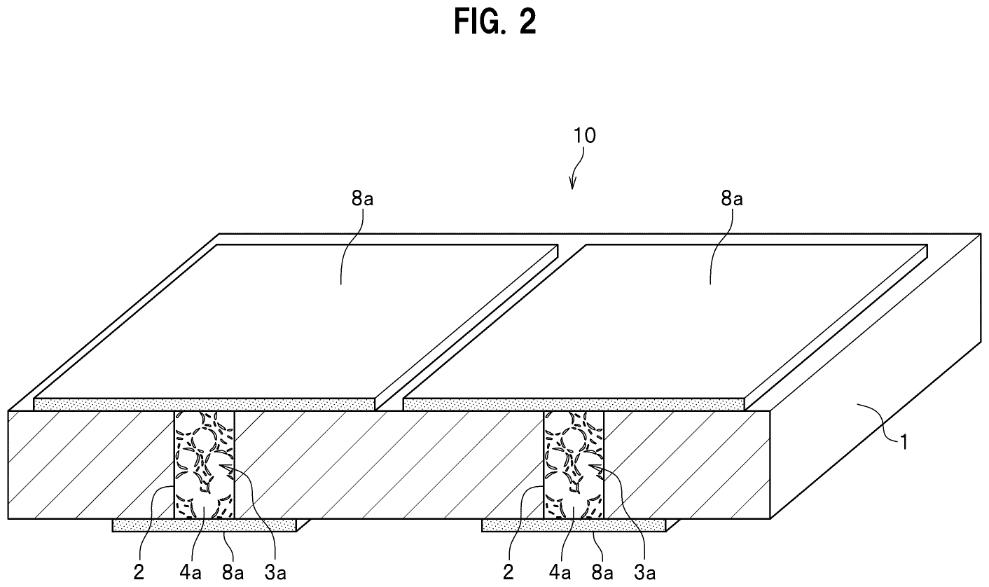

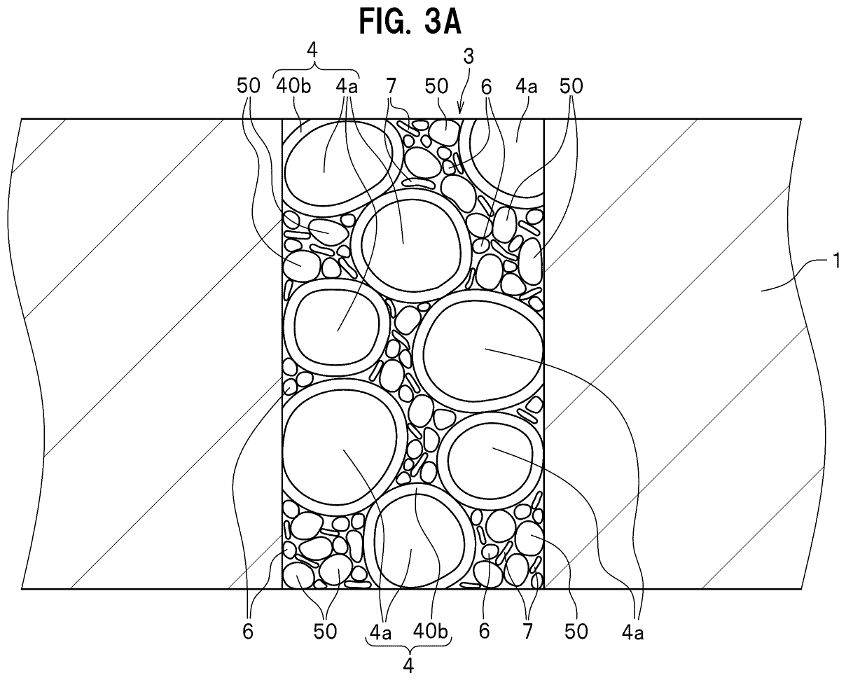

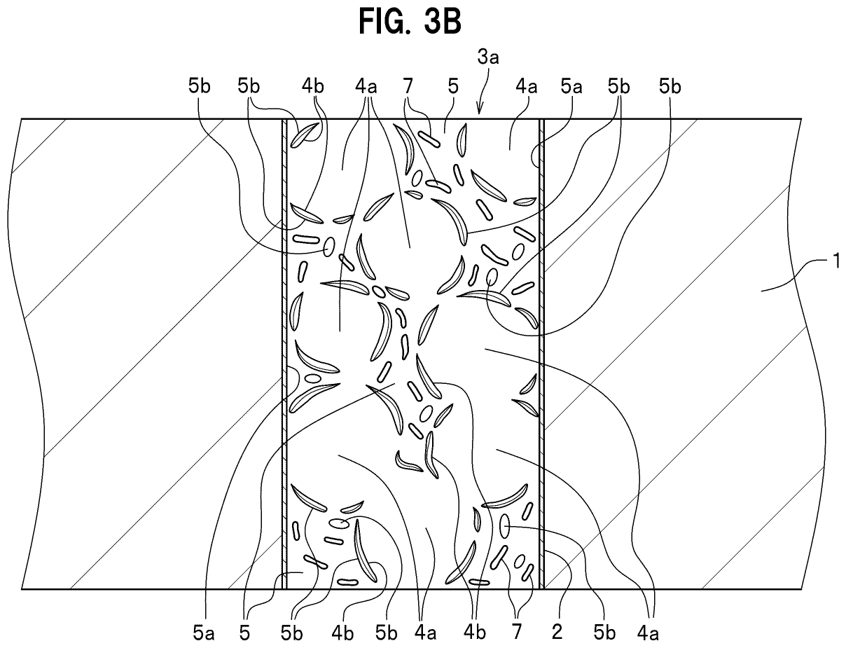

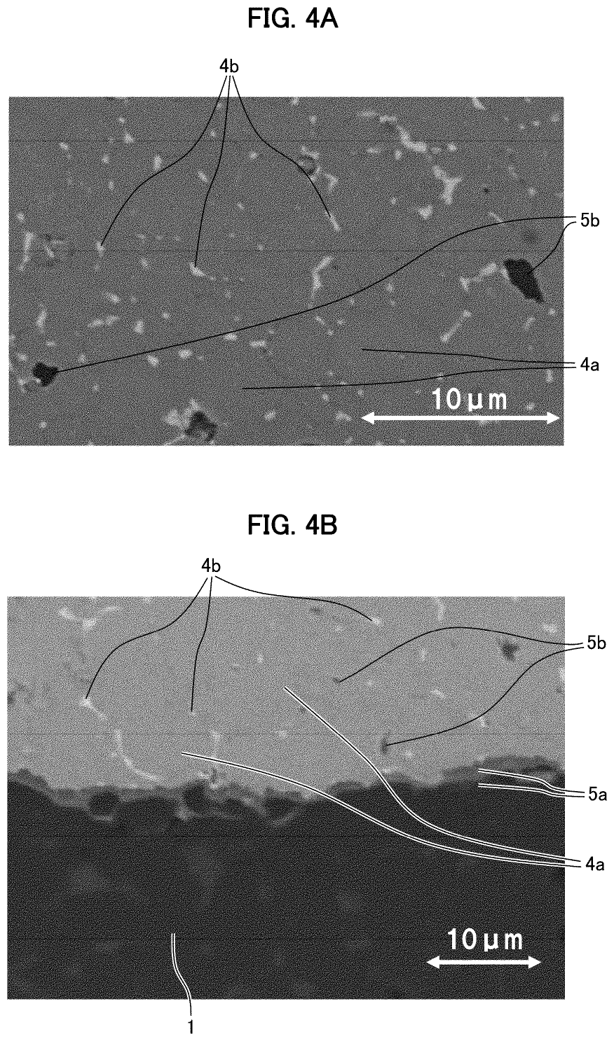

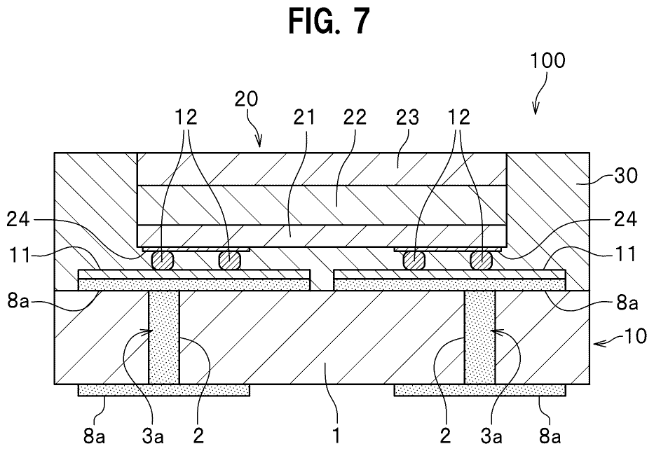

A ceramic sintered body substrate 10 according to an embodiment is described with reference to FIGS. 1 to 4B. FIG. 1 is a plan view schematically illustrating the ceramic sintered body substrate according to the embodiment, and FIG. 2 is a cross-sectional perspective view schematically illustrating the ceramic sintered body substrate according to the embodiment. FIG. 3A is an enlarged cross-sectional view schematically illustrating a state in which a first metal paste is disposed in a through hole of the ceramic sintered body substrate according to the embodiment. FIG. 3B is an enlarged cross-sectional view schematically illustrating a state of a first metal body after the ceramic sintered body substrate in FIG. 3A is sintered. FIG. 4A is an enlarged scanning electron microscope image showing the first metal body disposed in the through hole of the ceramic sintered body substrate according to the embodiment. FIG. 4B is an enlarged scanning electron microscope image showing the first metal body disposed in the through hole of the ceramic sintered body substrate according to the embodiment. FIG. 7 is a cross-sectional view schematically illustrating a light-emitting device according to an embodiment. Note that FIG. 3A illustrates a state before the ceramic sintered body substrate is sintered. FIG. 4A illustrates a state in the through hole, and FIG. 4B illustrates a state in the vicinity of an interface between the through hole and a ceramic substrate 1.

The ceramic sintered body substrate 10 includes the ceramic substrate 1 having a through hole 2 and a first metal body 3a disposed in the through hole 2. The first metal body 3a includes a plurality of particles of metal powder 4a, a second metal 4b, and a metal compound 5. Here, the term “the plurality of particles of metal powder 4a” does not mean that metal powder having a clear interface is present, but means that a plurality of particles of metal powder presumed to be aggregated from the presence of voids or the state of metal components are recognized in a cross-sectional view of the first metal body 3a. That is, it is not a state in which the metal powder is completely melted and no interface is present. When there is metal powder that is presumed to be one particle of metal powder because of having a reactant 5b of the metal compound 5 on the surfaces and the grain boundaries of the metal powder 4a, the metal powder may be counted as one particle of metal powder 4a even though a part of the metal powder is bonded to another metal powder. The metal powder 4a has a higher melting point than the second metal 4b and is dispersed in the second metal 4b that is continuous. The ceramic substrate 1 has a reaction layer 5a of the metal compound 5 on an inner wall of the through hole 2, and the reactant 5b of the metal compound 5 on the surfaces and grain boundaries of the metal powder 4a. However, the first metal body may be referred to as a first metal paste before firing, and a conductor may be referred to as a conductive paste before firing. Although the state of a fired product is different from that of a raw material, the fired product may be expressed by the name of the raw material for convenience of explanation. Although the ceramic substrate has different properties between before and after firing, it is described as a ceramic substrate.

Components of the ceramic sintered body substrate 10 are described below.

### Ceramic Substrate

The ceramic substrate 1 is a member having a plate shape and serving as a base of the ceramic sintered body substrate 10. The ceramic substrate 1 has, for example, a rectangular shape in the plan view. Note that the shape of the ceramic substrate 1 in the plan view is not particularly limited. The ceramic substrate 1 preferably contains at least one selected from silicon nitride, aluminum nitride, and boron nitride. For the ceramic substrate 1, a nitride ceramic such as silicon nitride, aluminum nitride, or boron nitride may preferably be used, but an oxide ceramic such as aluminum oxide, silicon oxide, calcium oxide, or magnesium oxide may be used. For the ceramic substrate 1, silicon carbide, mullite, borosilicate glass, or the like may also be used.

In the ceramic substrate 1, the through hole 2 is formed at a predetermined position in a plate thickness direction, and the first metal body 3a is disposed inside the through hole 2. In the ceramic substrate 1, each conductor 8a is in contact with at least a part of the first metal body 3a. Note that here, the conductor 8a is in contact with at least a part of the first metal body 3a disposed in the through hole 2, on each of the front and back surfaces of the ceramic substrate 1. The conductor 8a is used as a wiring, a wiring pad, or an external connection electrode for electrical connection with a light-emitting element 20.

The through hole 2 of the ceramic substrate 1 is a via hole for electrically connecting an element electrode 24 of the light-emitting element 20 to the outside of the ceramic substrate 1 via the first metal body 3a disposed inside the through hole 2. The through hole 2 is formed in a sintered ceramic substrate or a green sheet of a ceramic substrate before firing by mechanical processing such as drilling or laser processing, or is formed in the sintered ceramic substrate 1 by chemical processing such as etching. The through hole 2 preferably has a substantially circular shape or a circular shape when the ceramic substrate 1 is cut horizontally. The diameter of the through hole 2 is preferably in a range from 0.05 mm to 0.5 mm. When the diameter of the through hole 2 is equal to or greater than 0.05 mm, the first metal body 3a is easily and accurately disposed. When the diameter of the through hole 2 is equal to or less than 0.5 mm, the through hole 2 can be filled with an appropriate amount of the first metal body 3a while maintaining high strength and a low electric resistance value.

### First Metal Body

The first metal body 3a is disposed in the through hole 2 of the ceramic substrate 1. The first metal body 3a is a member electrically connected to the light-emitting element 20, solely or together with the conductor 8a. For example, the first metal body 3a includes the metal powder 4a, the second metal 4b, and the metal compound 5. The reaction layer 5a of the metal compound 5 is formed on an inner surface defining the through hole 2, and the reactant 5b of the metal compound 5 is formed on the surfaces or grain boundaries of the second metal 4b disposed around the metal powder 4a. However, here, the first metal paste 3 is described as including an inorganic filler 7 other than metal.

For example, the first metal paste 3 includes a first metal powder including the metal powder 4a and a covering metal member 40b to be the second metal 4b in a range from 63 mass % to 85 mass %, an active metal powder in a range from 1 mass % to 15 mass %, and an organic binder 6 serving as a solvent in a range from 5 mass % to 15 mass %, before sintering. The first metal paste 3 becomes a first metal body after firing. The covering metal member 40b becomes the second metal 4b after firing. An active metal powder 50 becomes the metal compound 5 after firing. The first metal body 3a includes the metal powder 4a in a range from 60 mass % to 80 mass %, the second metal 4b in a range from 3 mass % to 25 mass %, and the reactant 5b of the metal compound 5 in a range from 1 mass % to 15 mass %. The reaction layer 5a of the metal compound 5 is segregated on the inner surface defining the through hole 2. The inorganic filler 7 is dispersed in the first metal body 3a.

The metal powder 4a is a metal powder serving as a core of the first metal powder 4 when the first metal paste 3 is disposed. A median diameter of the metal powder 4a is preferably in a range from 1 μm to 50 μm, more preferably in a range from 5 μm to 40 μm. When the median diameter of the metal powder 4a is 1 μm or more, the metal powder 4a is easily covered with the second metal being the covering metal member 40b before firing. When the median diameter of the metal powder 4a is 50 μm or less, the metal powder 4a is easily disposed in relation to the size of the through hole 2. The metal powder 4a is covered with the covering metal member 40b having a lower melting point than the metal powder 4a, before sintering. The metal powder 4a is in a state of being dispersed in the first metal paste together with the active metal powder 50, the organic binder 6, and the inorganic filler 7. The metal powder 4a is dispersed in the second metal 4b after firing.

That is, the covering metal member 40b covering the metal powder 4a is melted by firing, and the peripheries of portions of the covering metal member 40b cover each other and are partially continuous. In the molten covering metal member 40b, the metal powder 4a is held in the dispersed state. This is because the molten covering metal member 40b has a high viscosity in a small amount, so that the metal powder 4a hardly settles or floats. In addition, the metal powder 4a maintains its particle size by being fired in an unmelted state.

That is, the metal powder 4a is melted and becomes liquid when heated to the melting point or above, but here, because the metal powder 4a is heated to below the melting point, the metal powder 4a itself is not melted and does not become liquid. Because the metal powder 4a is not melted and does not become liquid, the metal powder 4a does not flow to a large extent in the first metal paste 3. This can suppress the surface of the first metal paste 3 from sinking and becoming a significantly recessed surface. However, even at a temperature below the melting point of the metal powder 4a, a part of the surface of the metal powder 4a is in a softened state due to a reaction with the covering metal member 40b, so that the metal powder 4a is disposed in a state of contact or mixture with another particle of the metal powder 4a or the second metal 4b. At this time, an interface may exist between the metal powder 4a and the second metal 4b, but no interface may exist therebetween. In this way, because no interface can exist between the metal powder 4a and the second metal 4b, an electric resistance value can be decreased, and electrical conductivity and thermal conductivity can be increased.

In addition, because the first metal powder 4 in the first metal paste 3 is disposed at a high density, there are few voids and stress is low even after firing, so that reliability such as cooling and heating cycle characteristics is high. The metal powder 4a preferably includes at least one selected from, for example, Cu, Cr, and Ni. The metal powder 4a also includes an alloy including Cu, Cr, or Ni as a main component. The metal powder 4a is particularly preferably Cu or a Cu alloy. The melting point of the metal powder 4a is preferably in a range from 1050° C. to 2500° C. When the melting point of the metal powder 4a is 1050° C. or more, the difference in melting point between the metal powder 4a and the second metal 4b or the metal compound 5 to be described below is increased, so that the dispersion state can be improved. When the melting point of the metal powder 4a is 2500° C. or less, adverse effects on other members can be reduced.

The second metal 4b is disposed at a position surrounding at least a part or all of the metal powder 4a. The second metal 4b has a lower melting point than the metal powder 4a, and preferably includes at least one selected from, for example, Ag, Al, Zn, Sn, and an Ag—Cu alloy. In particular, Ag and an Ag—Cu alloy are preferable. Because the melting point of Ag is about 962° C. and the melting point of the Ag—Cu alloy is about 780° C., the difference in melting point with the metal powder 4a can be reduced. The second metal 4b is disposed around the metal powder 4a to a thickness in a range from 3% to 30% of the diameter or major axis of the metal powder 4a before melting, and is melted by firing and positioned around the metal powder 4a.

That is, because the metal powder 4a is covered with a predetermined thickness of the second metal 4b, particles of the metal powder 4a do not come into contact with each other or are not separated from each other more than necessary even after firing. In this way, because the metal powder 4a is appropriately dispersed, uneven heat distribution in the through hole can be suppressed. The melting point of the second metal 4b is preferably in a range from 200° C. to 1000° C., more preferably in a range from 500° C. to 980° C., particularly preferably in a range from 750° C. to 970° C. This is because when the melting point of the second metal 4b is 200° C. or more, the second metal 4b can withstand a reflow temperature or the like when the light-emitting device is manufactured. When the melting point of the second metal 4b is 1000° C. or less, because it has a predetermined difference from the melting point of the metal powder 4a, the metal powder 4a does not melt, and the dispersion state of the metal powder 4a can be improved. The difference between the melting points of the second metal 4b and the metal powder 4a is at least 50° C. or more, preferably 100° C. or more. Although the second metal 4b is substantially the same material as the covering metal member 40b, because the covering metal member 40b is extremely thin, the covering metal member 40b may be melted at a firing temperature significantly lower than the melting point of the second metal 4b.

The covering metal member 40b before the melting of the second metal 4b preferably has a uniform thickness with respect to the metal powder 4a and covers the entire circumference of the metal powder 4a. The covering metal member 40b preferably has a thickness in a range from 3% to 30% of the diameter or the major axis of the metal powder 4a. When the covering metal member 40b before the melting of the second metal 4b covers a part of the metal powder 4a, the covering metal member 40b preferably covers the metal powder 4a such that the thickness of a thin portion of the covering metal member 40b is 3% or more of the diameter or the major axis of the metal powder 4a and the thickness of a thick portion thereof is 30% or less of the diameter or the major axis of the metal powder 4a. When the ceramic substrate 1 contains nitrogen, the reactant 5b of the metal compound 5 is formed on the surface of the metal powder 4a or in the second metal 4b after firing. The case in which the ceramic substrate 1 contains nitrogen is, for example, a case in which at least one selected from silicon nitride, aluminum nitride, and boron nitride is used. In addition, the second metal 4b forms the reaction layer 5a of the metal compound 5 on the inner surface defining the through hole 2, together with the components of the metal compound 5.

The metal compound 5 may be disposed between particles of the metal powder 4a. At least a part or all of the active metal powder 50 becomes the metal compound 5 by firing. The active metal powder 50 is dispersed in the first metal paste 3, and the metal compound 5 after firing is also dispersed in the first metal body 3a. For example, titanium hydride (TiH₂) is described as an example of the active metal powder 50. The titanium hydride releases hydrogen by firing to become titanium metal, and then titanium is oxidized or nitrided into titanium oxide, titanium nitride, or the like. When the ceramic substrate 1 contains nitrogen, the active metal powder 50 included in the first metal paste 3 reacts with the nitrogen in the ceramic substrate 1, so that the reaction layer 5a of the metal compound 5 is formed at the interface between the first metal paste 3 and the ceramic substrate 1. The reactant 5b of the metal compound 5 is disposed in the spaces between particles of the metal powder 4a continuously or at the grain boundary. The metal compound 5 is directly in contact with the metal powder 4a, is in contact with or surrounds the second metal 4b, or surrounds the inorganic filler 7. As described above, the metal compound 5, together with the components of the second metal 4b, forms the reaction layer 5a on a part or all of the inner surface defining the through hole 2, thereby improving the adhesion strength between the first metal body 3a and the ceramic substrate 1.

Moreover, the melting points of the second metal 4b and the metal compound 5 are lower than the melting point of the metal powder 4a. Therefore, even when the metal powder 4a is fired in a state of being disposed in the through hole 2 as the first metal paste 3, the covering metal member 40b is melted, and the active metal powder 50 reacts, the metal powder 4a is maintained in a dispersed state. The second metal 4b melted from the covering metal member 40b is continuously disposed in the through hole 2. Here, the term “the second metal 4b is continuously disposed in the through hole 2” means that the second metal 4b is not physically connected from the upper end to the lower end of the through hole 2, is not unevenly distributed to one of the upper end and the lower end in the through hole 2, and is continuously disposed from the upper end to the lower end in the through hole 2 so as to be scattered between the plurality particles of metal powder 4a. That is, in general, when a metal is melted and becomes liquid, it tends to flow and is unevenly distributed; however, here, by disposing the covering metal member 40b so as to cover the metal powder 4a and firing the covering metal member 40b at a predetermined firing temperature, the flow of the covering metal member 40b caused by melting can be reduced, and the covering metal member 40b can be disposed in a dispersed manner from the upper end to the lower end of the through hole 2 without maldistribution. In the metal compound 5 formed by the reaction of the active metal powder 50, the reactant 5b is dispersed in the first metal body 3a, and the reaction layer 5a is disposed on the inner surface defining the through hole 2. Even though a difference exists in specific gravities between the metal powder 4a and the second metal 4b and between the metal powder 4a and the metal compound 5, the dispersion state can be maintained without settling or floating.

The active metal powder 50 is preferably one or more materials selected from, for example, TiH₂, CeH₂, ZrH₂, LaH₂, and MgH₂. Firing the active metal powder 50 causes all or part of hydrogen to be removed, react with nitrogen, oxygen, carbon, and the like included in the ceramic substrate 1, the inorganic filler 7, and the like, and turn into a nitride metal, an oxide metal, a carbide metal, and the like. This resultant substance is a metal compound. TiH₂ is particularly preferably used as the active metal powder 50, and the active metal powder 50 including TiH₂ reacts with nitrogen included in the ceramic substrate 1 or the like to form the reaction layer 5a such as TiH₂ at the interface with the ceramic sintered body substrate 10. This improves adhesion between the first metal body 3a serving as a conductive via and the ceramic substrate 1, so that the first metal body 3a firmly adheres to the through hole 2.

The inorganic filler 7 is dispersed in the first metal paste 3 to reduce the occurrence of cracking. Examples of the inorganic filler 7 include a ceramic filler, a metal filler, and a glass filler. Specifically, aluminum oxide, silicon oxide, or the like may be used as the inorganic filler 7. The inorganic filler 7 is contained in a content to the extent that does not interfere with the effects of other inclusions.

The organic binder 6 is a member contained in the first metal paste 3 before firing. The organic binder 6 is evaporated after firing and does not remain in the first metal paste 3. The organic binder 6 may be, for example, a solvent and a resin material generally used as a via material.

The conductors 8a are a conductive member that forms a wiring, a wiring pad, an external connection electrode, or the like of a wiring pattern set in advance. Each conductor 8a may be formed by firing a conductive paste 8. The conductive paste 8 is in contact with at least a part of the first metal paste 3 or the first metal body 3a. A thickness of the conductive paste 8 is preferably in a range from 12 μm to 35 μm, for example. The wiring or connection pads of the conductive paste 8 can be formed by, for example, etching, printing, or the like.

The conductive pastes 8 are disposed as a wiring or the like on a first surface of the ceramic substrate 1, and as a wiring or the like on a second surface opposite to the first surface. The conductive pastes 8 are each formed in a rectangular shape, a circular shape, a linear shape, or the like in a plan view, are disposed on the first surface of the ceramic substrate 1 so as to be separated from each other, and are disposed on the second surface so as to be separated from each other. The size of the conductive paste 8 disposed on the first surface of the ceramic substrate 1 and the size of the conductive paste 8 disposed on the second surface are different from each other in such a manner that the area of the conductive paste 8 disposed on the first surface is larger than that of the conductive paste 8 disposed on the second surface, for example; however, the sizes of the conductive pastes 8 may be the same. As an example, the conductive paste 8 is illustrated as a rectangle to be in contact with the entire circular first metal paste in a top view; however, the shape and the placement thereof are discretionary and are not limited.

The conductive paste 8 is preferably formed of the same material as that of the first metal paste 3, for example. As the material of the conductor 8a, copper foil may be used as a metal member. Examples of the material of the conductive paste 8 include a single substance such as gold, silver, copper, platinum, and aluminum, an alloy thereof, and a mixture of a mixed powder thereof and a resin binder. Examples of the resin binder include a thermosetting resin such as an epoxy resin and a silicone resin. The conductive paste 8 preferably includes a reducing agent such as an organic acid. This allows reduction in the electrical resistance in the connection with the light-emitting element 20.

Because the first metal paste 3 is firmly bonded to the inner surface of the ceramic substrate 1 that defines the through hole 2, the ceramic sintered body substrate 10 having the above configuration has high reliability and can have an ensured electrical connection with the light-emitting element.

Note that the number of through holes 2 in the ceramic substrate 1 may be two or more, and the shape thereof is not limited to a circular shape such as an elliptical shape, a rectangular shape or the like.

The shape of the conductor 8a may be a square shape, a rectangular shape, a trapezoidal shape, or a shape including a curved portion. The light-emitting element 20 may be directly connected to a part of the first metal body 3a without providing the conductor 8a.

### Method for Manufacturing Ceramic Sintered Body Substrate

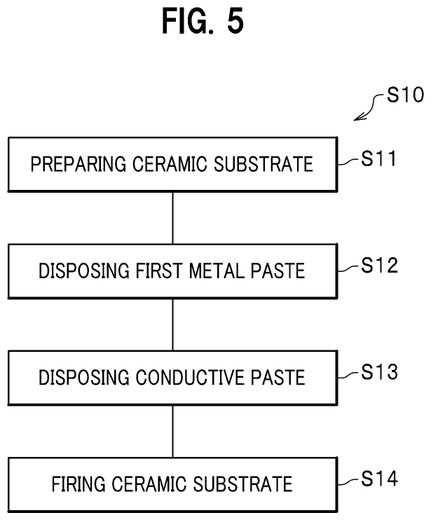

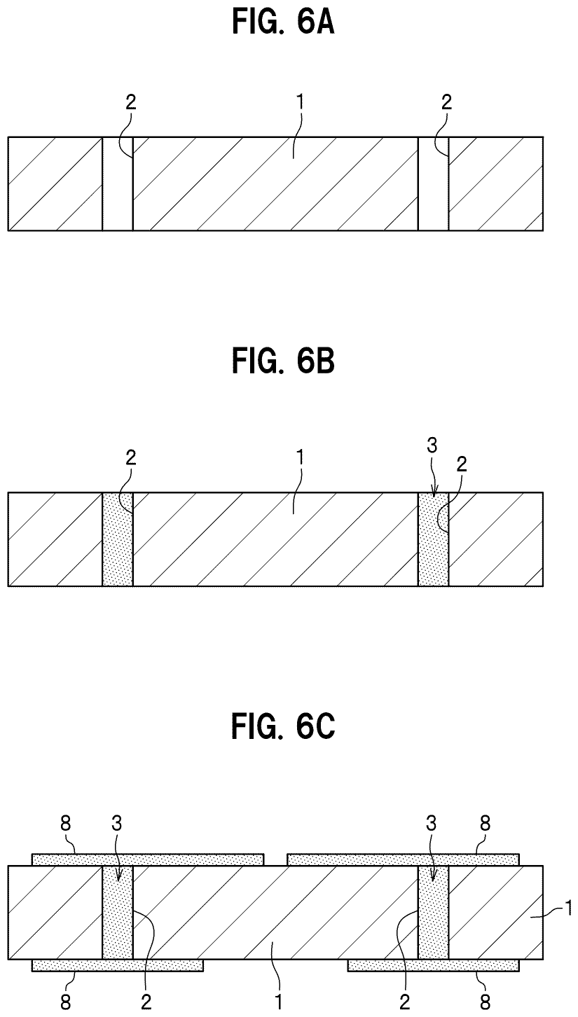

A method for manufacturing the ceramic sintered body substrate according to the embodiment is described below with reference to FIGS. 5 to 6C. FIG. 5 is a flowchart exemplifying the method for manufacturing the ceramic sintered body substrate according to the embodiment. FIG. 6A is a cross-sectional view schematically illustrating a prepared ceramic substrate in the method for manufacturing the ceramic sintered body substrate according to the embodiment. FIG. 6B is a cross-sectional view schematically illustrating a state in which a first metal paste is disposed in a through hole in the method for manufacturing the ceramic sintered body substrate according to the embodiment. FIG. 6C is a cross-sectional view schematically illustrating a state in which a conductive paste is disposed in the method for manufacturing the ceramic sintered body substrate according to the embodiment.

A method S10 for manufacturing the ceramic sintered body substrate includes S11 of preparing a ceramic substrate provided with a through hole before firing, S12 of disposing the first metal paste in the through hole, and S14 of firing the ceramic substrate provided with the first metal paste. In S12 of disposing the first metal paste, the first metal paste includes a plurality of particles of first metal powder and a plurality of particles of active metal powder, and the first metal powder includes a metal powder serving as a core and a covering metal member having a lower melting point than the metal powder and covering at least a part of the metal powder. In S14 of firing the ceramic substrate, a firing temperature is a temperature in a range from 700° C. to less than the melting point of the metal powder. The method S10 for manufacturing the ceramic sintered body substrate is described as an example in which, after S12 of disposing the first metal paste, S13 of disposing a conductive paste on the ceramic substrate is performed so as to be at least partially in contact with the first metal paste, before S14 of firing the ceramic substrate.

### Preparing Ceramic Substrate

In S11 of preparing the ceramic substrate (hereinafter, referred to as step S11), for example, a substrate having a flat plate shape is prepared. In step S11, the prepared ceramic substrate 1 is provided with the through holes 2 by laser processing or the like, the through holes 2 corresponding in number to connection portions such as the element electrodes 24 of the light-emitting element 20 to be described below. When the number of the light-emitting element 20 disposed on the ceramic substrate 1 is one, for example, the through holes 2 are formed at two positions. Note that the ceramic substrate 1 may be prepared in a state in which the through holes 2 corresponding in number to the element electrodes 24 and corresponding to the size of an area in which a plurality of light-emitting elements 20 are disposed, or may be prepared by being cut into a size for disposing a predetermined number of light-emitting elements 20.

### Disposing First Metal Paste

Step S12 of disposing the first metal paste (hereinafter, referred to as step S12) is to dispose the first metal paste in the through hole 2 formed in the ceramic substrate 1. In step S12, the first metal paste 3 is disposed in the through hole 2, for example, by screen printing or injection using a nozzle. The first metal powder 4 includes the metal powder 4a serving as a core and the covering metal member 40b covering the metal powder 4a.

When the first metal paste 3 is disposed in the through hole 2 in step S12, it is preferable to dispose the first metal paste in the through hole 2 from the first surface being one surface of the ceramic substrate 1 by using, for example, a squeegee as a tool used for screen printing, and to dispose the first metal paste in the through hole 2 from the second surface being the other surface of the ceramic substrate 1 by using a squeegee as in the first surface.

Subsequently, S13 of disposing the conductive paste 8 (hereinafter, referred to as step S13) is performed. In step S13, the conductive paste 8 is disposed on the ceramic substrate 1 so as to be at least partially in contact with the first metal paste 3 disposed in the through hole 2. In step S13, the conductive paste 8 is disposed in contact with the entire surface of the first metal paste 3 exposed from the through hole 2 of the ceramic substrate 1. For example, the conductive paste 8 is disposed in a rectangular shape at a total of four positions including two positions on the first surface of the ceramic substrate 1 and two positions on the second surface of the ceramic substrate 1. Subsequently, as the conductive paste 8, a rectangular wiring or wiring pad is disposed on the first surface and the second surface of the ceramic substrate 1 through a mask by screen printing, metal mask printing, or the like.

Note that the first metal paste 3 and the conductive paste 8 used in step S12 and step S13 have fluidity and can be freely disposed in the through hole 2 having an discretionary shape, and can be disposed by being cured after being applied in an discretionary shape and with an discretionary thickness.

Subsequently, S14 of firing the ceramic substrate (hereinafter, referred to as step S14) is performed. In step S14, the firing temperature is in a range from 700° C. to less than the melting point of the metal powder. In step S14, when the firing operation is performed, the firing atmosphere is preferably an Ar atmosphere of 99.9% or more or a vacuum atmosphere of 10⁻⁵ Pa or less. In step S14, the firing temperature is preferably in a range from 700° C. to 1000° C., more preferably in a range from 700° C. to 980° C., particularly preferably in a range from 750° C. to 970° C.

Through step S14, the ceramic sintered body substrate 10 can be manufactured. As illustrated in FIGS. 3B and 4, when the state of the first metal paste 3 is observed after firing, for example, the copper powder being the metal powder 4a maintains the state of being dispersed in the Ag—Cu alloy being the second metal 4b that is continuous, similarly to the state before firing. This is because, by adjusting the firing temperature to be equal to or lower than a predetermined temperature as described above, the metal powder 4a is not melted, and the second metal 4b formed by the melting of the covering metal member 40b and the metal compound 5 formed by the reaction of the active metal powder 50 are disposed between particles of the metal powder 4a. After firing, due to the metal compound 5 formed by the reaction of the active metal powder 50, the reactant 5b of the metal compound 5 is formed on the surface of the covering metal member 40b before melting, and the reaction layer 5a of the metal compound 5 is formed on the inner surface of the ceramic substrate 1 that defines the through hole 2. In this way, the reaction layer 5a of the metal compound 5 is formed by the first metal paste 3 after firing, so that the first metal paste 3 is strongly bonded to the through hole 2. Accordingly, in the ceramic sintered body substrate 10, because the dispersion state of the metal powder 4a is relatively uniform in the electrical connection performed via the first metal body 3a, the conductivity is stabilized. In addition, because the reaction layer 5a of the metal compound 5 is formed, the bonding strength between the first metal paste and the inner surface defining the through hole 2 is high, and a configuration with high reliability can be implemented.

### Light-Emitting Device

A light-emitting device 100 according to the embodiment is described below with reference to FIG. 7. The light-emitting device 100 is a device in which the light-emitting element 20 is disposed on the ceramic sintered body substrate 10 to emit light. Although the number of light-emitting elements 20 is one in the drawing, the number of light-emitting elements 20 may be more than one. The arrangement thereof is not particularly limited; for example, the light-emitting elements 20 may be arranged in a line.

The light-emitting device 100 includes the ceramic sintered body substrate 10 described above and the light-emitting element 20 electrically connected to the conductor 8a serving as the wiring of the ceramic sintered body substrate 10. Note that in the light-emitting device 100, a light reflective member 30 covering the lateral surfaces of the light-emitting element 20 and the upper surface of the ceramic sintered body substrate 10 is disposed as an example. In the ceramic sintered body substrate 10, various patterns of wirings can be formed depending on the application.

### Light-Emitting Element

The light-emitting element 20 includes a pair of element electrodes 24, a light-transmissive member 23 disposed on a light extraction surface side of the light-emitting element 20, an element substrate 22, and a semiconductor layered body 21.

The light-emitting element 20 includes, for example, the semiconductor layered body 21 on the element substrate 22, and in the present embodiment, the light-transmissive member 23 is disposed on an upper surface side of the element substrate 22 serving as a light extraction surface, the semiconductor layered body 21 is provided on a lower surface side of the element substrate 22, and the pair of element electrodes 24 are provided on the semiconductor layered body 21 side. The semiconductor layered body 21 can have discretionary composition according to the desired emission wavelength. For example, a nitride semiconductor that can emit blue or green light (In_{X}Al_{Y}Ga_{1-X-Y}N, 0≤X, 0≤Y, X+Y≤1), GaP, GaAlAs or AlInGaP that can emit red light, or the like can be used. The size and the shape of the light-emitting element 20 can be appropriately selected in accordance with the purpose of use. As an example, a sapphire substrate or a silicon substrate is used as the element substrate 22.

For example, the light-transmissive member 23 is formed of a light-transmissive resin material, and an epoxy resin, a silicone resin, a resin in which an epoxy resin and a silicone resin are mixed, or the like can be used. The light-transmissive member 23 may contain a phosphor, and for example, when the light-transmissive member 23 contains a phosphor that absorbs blue light from the light-emitting element 20 and emits yellow light, white light can be emitted from the light-emitting element 20. The light-transmissive member 23 may further contain a plurality of types of phosphors, and for example, when the light-transmissive member 23 contains a phosphor that absorbs blue light from the semiconductor layered body 21 and emits green light and a phosphor that absorbs blue light therefrom and emits red light, white light can be emitted from the light-emitting element 20.

Examples of the phosphor include an yttrium aluminum garnet-based phosphor (Y₃(Al,Ga)₅O₁₂:Ce, for example), a lutetium aluminum garnet-based phosphor (Lu₃(Al,Ga)₅O₁₂:Ce, for example), a terbium aluminum garnet-based phosphor (Tb₃(Al,Ga)₅O₁₂:Ce, for example), nitride phosphors, such as a β-SiAlON phosphor ((Si,Al)₃(O,N)₄:Eu, for example), an α-SiAlON phosphor (Mz(Si,Al)₁₂(O,N)₁₆ (where 0<z≤2, and M is Li, Mg, Ca, Y, or a lanthanide element excluding La and Ce)), a CASN-based phosphor (CaAlSiN₃:Eu, for example), and an SCASN-based phosphor ((Sr,Ca)AlSiN₃:Eu, for example), fluoride phosphors, such as a KSF-based phosphor (K₂SiF₆:Mn, for example), a KSAF-based phosphor (K₂(Si,Al)F₆:Mn, for example), and an MGF-based phosphor (3.5MgO·0.5MgF₂·GeO₂:Mn, for example), quantum dot phosphors, such as perovskite and chalcopyrite, and the like.

Each element electrode 24 is connected to the conductor 8a of the ceramic sintered body substrate 10 by using metal bumps 12 via a bonding member 11. The conductor 8a is preferably subjected to surface treatment such as plating in which Ni, Pd, and Au are layered in this order. One of the element electrodes 24 is a p-electrode, and the p-electrode is disposed at a distance from the other element electrode 24, that is, an n-electrode so as not to be electrically short-circuited therewith. As an example, the element electrodes 24 have a configuration in which one p-electrode and one n-electrode are disposed, but may have a configuration in which two p-electrodes or two n-electrodes are respectively disposed at two positions and the other electrode of one p-electrode or one n-electrode is disposed at one position.

The metal bumps 12 electrically connect the element electrode 24 and the conductor 8a. The metal bumps 12 may be disposed either on the element electrode 24 side or on the conductor 8a side. The shape, size, and number of the metal bumps 12 can be appropriately set as long as they can be disposed within the range of the element electrodes 24. The size of the metal bump 12 can be appropriately adjusted according to the size of the semiconductor layered body, the required light emission output of the light-emitting element, and the like. For example, the metal bump 12 may have a diameter of about several tens of m to several hundreds of m.

The metal bumps 12 can be formed of, for example, Au, Ag, Cu, Al, Sn, Pt, Zn, Ni, or an alloy thereof, and can be formed of, for example, stud bumps known in the field. The stud bumps can be formed by a stud bump bonder, a wire bonding apparatus, or the like. The metal bumps 12 may also be formed by a method known in the art such as electroplating, electroless plating, vapor deposition, or sputtering.

For example, the metal bumps 12 are bonded via the bonding member 11. Examples of the bonding member 11 used herein include solders such as tin-bismuth based solders, tin-copper based solders, tin-silver based solders, and gold-tin based solders, eutectic alloys such as alloys containing Au and Sn as main components, alloys containing Au and Si as main components, and alloys containing Au and Ge as main components, paste materials of silver, gold, palladium, and the like, anisotropic conductive materials such as ACP and ACF, brazing filler metals of low melting point metals, and conductive adhesives and conductive composite adhesives of a combination of any of these.

### Light Reflective Member

The light reflective member 30 is a member having light reflectivity. The light reflective member 30 covers the first surface of the ceramic sintered body substrate 10 and the lateral surfaces of the light-emitting element 20. The light reflective member 30 is disposed such that a light extraction surface of the light-emitting element 20 is exposed, and such that the light reflective member 30 is flush with the light-transmissive member 23 of the light-emitting element 20. For example, the light reflective member 30 is also disposed between the lower surface of the light-emitting element 20 and the first surface of the ceramic sintered body substrate 10.

The light reflective member 30 preferably has a high reflectance in order that the light from the light-emitting element 20 can be efficiently used. The light reflective member 30 is preferably white. The reflectance of the light reflective member 30 is, for example, preferably 90% or more, and more preferably 94% or more at the wavelength of the light emitted from the light-emitting element 20.

Examples of a resin used for the light reflective member 30 include thermoplastic resins, such as acrylic resin, polycarbonate resin, cyclic polyolefin resin, polyethylene terephthalate resin, polyethylene naphthalate resin, and polyester resin, and thermosetting resins, such as epoxy resin and silicone resin. Examples of a light diffusing material that can be used include known materials such as titanium oxide, silica, alumina, zinc oxide, and glass.

Because the light-emitting device 100 having the above-described configuration includes the first metal body 3a in the ceramic sintered body substrate 10, the bonding strength between the first metal body 3a and the ceramic substrate 1 is high, and the reliability can be improved.

Although the light-emitting device 100 uses one light-emitting element 20 as one unit to control brightness and turning on/off, the number of light-emitting elements 20 included in one unit may be either one or more than one. For example, four light-emitting elements 20 arranged in one row and four columns or two rows and two columns, or nine light-emitting elements 20 arranged in three rows and three columns can be used as one unit.

### Method for Manufacturing Light-Emitting Device

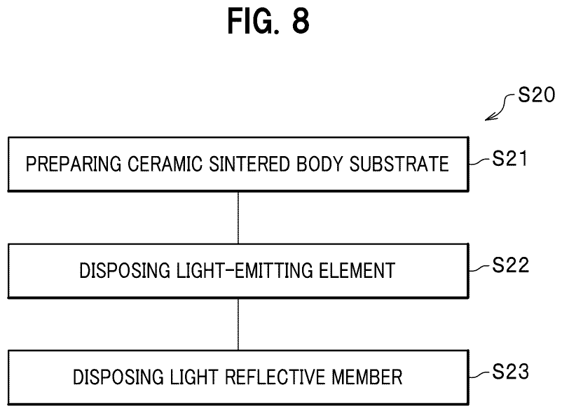

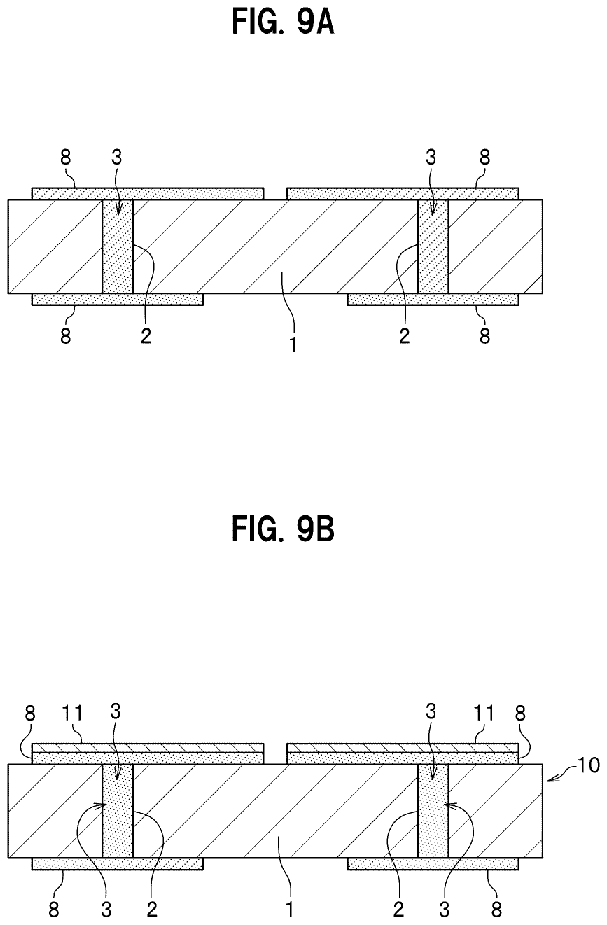

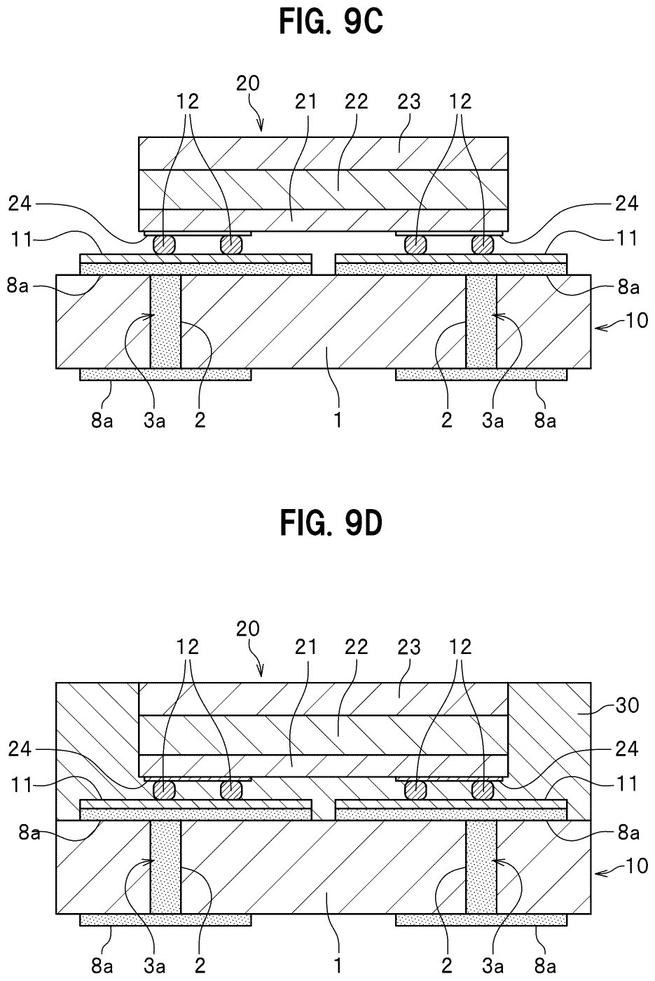

A method for manufacturing the light-emitting device according to the embodiment is described below with reference to FIGS. 8 to 9D. FIG. 8 is a flowchart exemplifying the method for manufacturing the light-emitting device according to the embodiment. FIG. 9A is a cross-sectional view schematically illustrating a prepared ceramic sintered body substrate in the method for manufacturing the light-emitting device according to the embodiment. FIG. 9B is a cross-sectional view schematically illustrating a state in which a convenience member is disposed on the ceramic sintered body substrate. FIG. 9C is a cross-sectional view schematically illustrating a state in which a light-emitting element is disposed in the method for manufacturing the light-emitting device according to the embodiment. FIG. 9D is a cross-sectional view schematically illustrating a state in which a light reflective member is disposed in the method for manufacturing the light-emitting device according to the embodiment.

A method S20 for manufacturing the light-emitting device includes S21 of preparing the ceramic sintered body substrate manufactured by the method S10 for manufacturing the ceramic sintered body substrate described above, and S22 of disposing a light-emitting element on the ceramic sintered body substrate, and in S22 of disposing the light-emitting element, the first metal member disposed in the through hole is directly or indirectly electrically connected to the light-emitting element. The method S20 may include S23 of disposing a light reflective member after S22 of disposing the light-emitting element. In S22 of disposing the light-emitting element, the element electrodes 24 may be directly or indirectly connected to the conductor 8a in contact with at least a part of the first metal body 3a.

### Preparing Ceramic Sintered Body Substrate

S21 of preparing the ceramic sintered body substrate (hereinafter, referred to as step S21) is to prepare the ceramic sintered body substrate 10 manufactured by the method S10 for manufacturing the ceramic sintered body substrate described above. The conductors 8a are connected to the respective first metal bodies 3a disposed in the through holes 2, and are disposed at four positions on the first surface and the second surface of the ceramic sintered body substrate 10. The conductors 8a can be formed with the shape, size, and interval of the conductors 8a adjusted according to the element electrodes 24 of the light-emitting elements 20. Note that the ceramic sintered body substrate 10 may include a plurality of regions in which the light-emitting elements 20 are disposed, and may have a size to be singulated into individual light-emitting devices 100 after the light reflective member 30 to be described below is disposed, or the ceramic sintered body substrate 10 may have a size for each light-emitting device 100.

### Disposing Light-Emitting Element

S22 of disposing the light-emitting element (hereinafter, referred to as step S22) is to dispose the light-emitting element 20 on the ceramic sintered body substrate 10. In this step S22, the element electrodes 24 of the light-emitting element 20 are connected to the conductors 8a using the metal bumps 12 via the bonding members 11 disposed on the conductors 8a. As the bonding member 11 having conductivity, for example, a bump formed of gold, silver, copper, or the like, a conductive paste of a mixture of a resin binder and a metal powder of gold, silver, copper, platinum, aluminum, or the like, a tin-silver-copper (SAC) based solder, a tin-bismuth (SnBi) based solder, or the like can be used. Note that the light-emitting element 20 is disposed in a state in which the light-transmissive member 23 is connected to the element substrate 22 in advance. When the light-transmissive member 23 is bonded to the element substrate 22, a light-transmissive bonding material is used.

### Disposing Light Reflective Member

S23 of disposing the light reflective member (hereinafter, referred to as step S23) is to dispose the light reflective member 30 covering the first surface being the upper surface of the ceramic sintered body substrate 10 and covering the lateral surfaces of the light-emitting element 20. In step S23, the light reflective member 30 is disposed on the ceramic sintered body substrate 10 so as to surround the light-emitting element 20 and such that the upper surface of the light-transmissive member 23 serving as the light extraction surface of the light-emitting element 20 is exposed therefrom. The light reflective member 30 is disposed so as to have a rectangular shape in a plan view.

In the method S20 for manufacturing the light-emitting device, a singulation operation is performed as necessary after the operation of the step S23 is completed. For the light-emitting device 100, one unit of the light-emitting device 100 is set in advance by the number of the light-emitting elements 20 used. Therefore, when a plurality of the light-emitting devices 100 are manufactured at a time, the singulation operation is performed. When the singulation operation is performed, the plurality of light-emitting devices 100 are manufactured by performing cutting in a lattice pattern. For example, a rotating blade having a disk shape, an ultrasonic cutter, laser light irradiation, a blade, or the like can be used as the cutting method.

In the method S20 for manufacturing the light-emitting device having the above-described configuration, the bonding strength of the first metal paste 3 disposed in the through hole 2 of the ceramic substrate 1 is improved by the method S10 for manufacturing the ceramic sintered body substrate, whereby reliability is improved and stable control of the light-emitting element 20 is enabled.

### Application Example

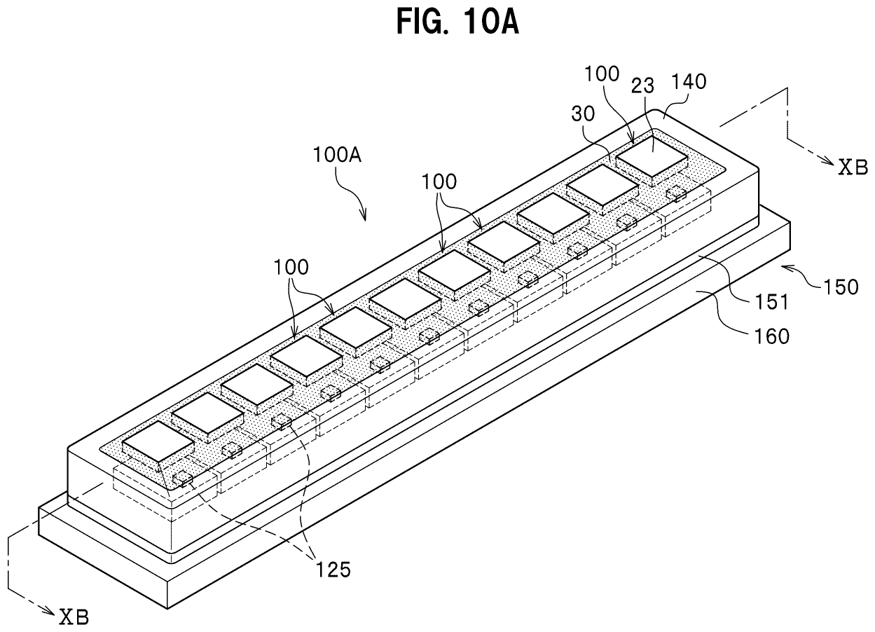

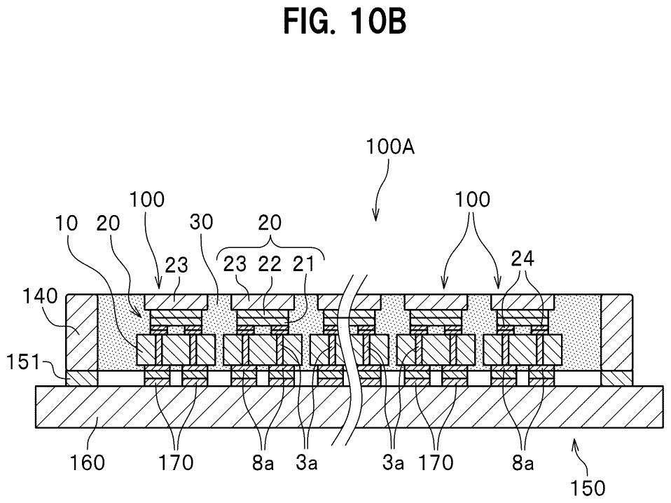

As illustrated in FIGS. 10A and 10B, a light-emitting module 100A including a plurality of (eleven in the drawing) light-emitting devices 100 in a line may be used. A configuration of the light-emitting module 100A is described below. FIG. 10A is a perspective view illustrating an application example of a light-emitting device. FIG. 10B is a cross-sectional view illustrating a cross section with a part of FIG. 10A omitted.

The light-emitting module 100A includes eleven light-emitting devices 100 in a line, a frame body 140 outside the light reflective member 30, and a module substrate 150 connected to the conductors 8a below the ceramic sintered body substrates 10.

The frame body 140 is a member for surrounding the light reflective member 30 that covers the plurality of light-emitting devices 100. The frame body 140 is formed in a rectangular annular shape that is, for example, rectangular in a plan view, and surrounds the periphery of the light reflective member 30. The frame body 140 can be formed using a member having a frame shape and formed of a metal, an alloy, or a ceramic. Examples of the metal include Fe, Cu, Ni, Al, Ag, Au, Al, Pt, Ti, W, and Pd. Examples of the alloy include an alloy containing at least one of Fe, Cu, Ni, Al, Ag, Au, Al, Pt, Ti, W, and Pd. A resin material may be used as the frame body 140. In this case, the metal, the alloy, or the ceramic member may be embedded in the frame body 140 formed of the resin material, or a part of the frame body 140 may be formed of a resin material and another part thereof may be formed of a metal, an alloy, or a ceramic member.

The module substrate 150 is a member on which the light-emitting device 100 is mounted, and electrically connects the light-emitting device 100 to the outside. The module substrate 150 is formed in a substantially rectangular shape in the plan view, for example. The module substrate 150 includes a substrate portion 160 and wiring board portions 170.

As a material of the substrate portion 160, for example, an insulating material is preferably used, and a material that does not easily transmit light emitted from the light-emitting element 20, external light, and the like is preferably used. Examples of the material of the substrate portion 160 include a ceramic such as alumina, aluminum nitride, or mullite, a thermoplastic resin such as polyamide, polyphthalamide, polyphenylene sulfide, or a liquid crystal polymer, and a resin such as an epoxy resin, a silicone resin, a modified epoxy resin, a urethane resin, or a phenol resin. In particular, a ceramic having excellent heat dissipation is preferably used.

The wiring board portions 170 are formed on the substrate portion 160 at positions facing the conductors 8a below the light-emitting devices 100. Examples of a material of the wiring board portions 170 include those exemplified as the materials used for the first metal body 3a, the conductor 8a, and the like.

Note that the module substrate 150 is bonded to the frame body 140 via a conductive adhesive 151, and is disposed such that the corresponding conductors 8a and the corresponding wiring board portions 170 are bonded. For example, a eutectic solder, a conductive paste, or a bump may be used for the conductive adhesive 151. In the light-emitting device 100, a protective element 125 is disposed on each ceramic sintered body substrate 10 in parallel with each light-emitting element 20.

Because the light-emitting module 100A is configured as described above, the light-emitting module 100A is driven as follows. That is, in the light-emitting module 100A, a current is supplied from an external power supply to the light-emitting elements 20 via the wiring board portions 170, the conductive paste, the first metal paste, and the element electrodes 24, so that the light-emitting elements 20 emit light. Of the light emitted from the light-emitting element 20, light traveling upward is extracted to the outside above the light-emitting device 100 via the light-transmissive member 23. Light traveling downward is reflected by the ceramic sintered body substrate 10 and is extracted to the outside of the light-emitting device 100 via the light-transmissive member 23. Light traveling between the light-emitting element 20 and the frame body 140 is reflected by the light reflective member 30 and the frame body 140 and extracted to the outside of the light-emitting device 100 via the light-transmissive member 23. Light traveling between the light-emitting elements 20 is reflected by the light reflective member 30 and extracted to the outside of the light-emitting device 100 via the light-transmissive member 23. At this time, if a space between the light-transmissive members 23 is narrow (for example, equal to or less than 0.2 mm), for example, when the light-emitting module 100A is employed for a light source of a vehicle headlight, a configuration of an optical system can be simplified and reduced in size.

Note that when the light-emitting module 100A is manufactured, the light-emitting devices 100 are arranged on a sheet member, the frame body 140 is disposed around the light-emitting devices 100, and the light reflective member 30 is provided in a space surrounded by the frame body 140 and the sheet member in this state, whereby the light reflective member 30 is disposed. Subsequently, the light-emitting devices 100 supported by the frame body 140 and the light reflective member 30 is disposed on the module substrate 150 on which the wiring board portions 170 and the conductive adhesive 151 are disposed, and thus the conductive pastes 8 is electrically connected to the wiring board portions 170, resulting in the manufacturing of the light-emitting module 100A.

The claims may have dependency as in [Clause 1] to [Clause 24].

### [Clause 1]

A method for manufacturing a ceramic sintered body substrate, comprising:
preparing a ceramic substrate provided with a through hole before firing;
disposing a first metal paste in the through hole; and
firing the ceramic substrate provided with the first metal paste, wherein
in the disposing of the first metal paste, the first metal paste comprises,
   a plurality of particles of first metal powder, and
   a plurality of particles of active metal powder, and
   the first metal powder comprises,
      a metal powder serving as a core, and
      a covering metal member having a melting point lower than a melting point of the metal powder and covering at least a part of the metal powder, and
      in the firing of the ceramic substrate, a firing temperature is a temperature in a range from 700° C. to less than the melting point of the metal powder.

### [Clause 2]

The method for manufacturing a ceramic sintered body substrate, according to clause 1, wherein in the disposing of the first metal paste, the metal powder contains at least one selected from Cu, Cr, and Ni.

### [Clause 3]

The method for manufacturing a ceramic sintered body substrate, according to clauses 1 or 2, wherein in the disposing of the first metal paste, the covering metal member contains at least one selected from Ag, Al, Zn, Sn, and an Ag—Cu alloy.

### [Clause 4]

The method for manufacturing a ceramic sintered body substrate, according to any one of clauses 1 to 3, wherein in the disposing of the first metal paste, the covering metal member has a thickness in a range from 3% to 30% of a diameter or major axis of the metal powder.

### [Clause 5]

The method for manufacturing a ceramic sintered body substrate, according to any one of clauses 1 to 4, wherein in the disposing of the first metal paste, a median diameter of the metal powder is in a range from 1 m to 50 km.

### [Clause 6]

The method for manufacturing a ceramic sintered body substrate, according to any one of clauses 1 to 5, wherein in the disposing of the first metal paste, the active metal powder contains at least one selected from TiH₂, CeH₂, ZrH₂, and MgH₂.

### [Clause 7]

The method for manufacturing a ceramic sintered body substrate, according to any one of clauses 1 to 6, wherein in the disposing of the first metal paste, the melting point of the metal powder is in a range from 1050° C. to 2500° C.

### [Clause 8]

The method for manufacturing a ceramic sintered body substrate, according to any one of clauses 1 to 7, wherein in the disposing of the first metal paste, the melting point of the covering metal member is in a range from 200° C. to 1000° C.

### [Clause 9]

The method for manufacturing a ceramic sintered body substrate, according to any one of clauses 1 to 8, wherein in the disposing of the first metal paste, the first metal paste further comprises an organic binder.

### [Clause 10]

The method for manufacturing a ceramic sintered body substrate, according to any one of clauses 1 to 9, wherein in the disposing of the first metal paste, the first metal paste further comprises a plurality of particles of inorganic fillers other than a metal.

### [Clause 11]

The method for manufacturing a ceramic sintered body substrate, according to any one of clauses 1 to 10, wherein in the firing of the ceramic substrate, the firing temperature is 1000° C. or less.

### [Clause 12]

The method for manufacturing a ceramic sintered body substrate, according to any one of clauses 1 to 11, wherein in the firing of the ceramic substrate, the firing temperature is 950° C. or less.

### [Clause 13]

The method for manufacturing a ceramic sintered body substrate, according to any one of clauses 1 to 12, wherein in the firing of the ceramic substrate, a firing atmosphere is an Ar atmosphere of 99.9% or more or a vacuum atmosphere of 10⁻⁵ Pa or less.

### [Clause 14]

The method for manufacturing a ceramic sintered body substrate, according to any one of clauses 1 to 13, wherein, after the disposing of the first metal paste, disposing of a conductive paste on the ceramic substrate is performed such that the conductive paste is at least partially in contact with the first metal paste, before the firing of the ceramic substrate.

### [Clause 15]

A method for manufacturing a light-emitting device, comprising:
preparing a ceramic sintered body substrate manufactured by the method for manufacturing a ceramic sintered body substrate according to any one of clauses 1 to 13; and
disposing a light-emitting element on the ceramic sintered body substrate, wherein
   in the preparing of the ceramic sintered body substrate, the first metal paste becomes a first metal body by firing, and
in the disposing of the light-emitting element, the first metal body disposed in the through hole is directly or indirectly electrically connected to the light-emitting element.

### [Clause 16]

A method for manufacturing a light-emitting device, comprising:
preparing a ceramic sintered body substrate manufactured by the method for manufacturing a ceramic sintered body substrate according to clause 14; and
disposing a light-emitting element on the ceramic sintered body substrate, wherein
   in the preparing of the ceramic sintered body substrate, the first metal paste becomes a first metal body and the conductive paste becomes a conductor, by firing, and
in the disposing of the light-emitting element, the first metal body disposed in the through hole or the conductor is directly or indirectly electrically connected to the light-emitting element.

### [Clause 17]

A ceramic sintered body substrate comprising:
a ceramic substrate provided with a through hole; and
a first metal body disposed in the through hole, wherein
the first metal body comprises a plurality of particles of metal powder, a second metal, and a metal compound, the metal powder having a melting point higher than a melting point of the second metal and being dispersed in the second metal that is continuous, and
the ceramic substrate comprises a reaction layer of the metal compound on an inner wall of the through hole, and a reactant of the metal compound on a grain boundary of the metal powder.

### [Clause 18]

The ceramic sintered body substrate according to clause 17, wherein the metal powder contains at least one selected from Cu, Cr, and Ni.

### [Clause 19]

The ceramic sintered body substrate according to clauses 17 or 18, wherein the second metal contains at least one selected from Ag, Al, Zn, Sn, and an Ag—Cu alloy.

### [Clause 20]

The ceramic sintered body substrate according to any one of clauses 17 to 19, wherein the ceramic substrate contains at least one selected from silicon nitride, aluminum nitride, and boron nitride.

### [Clause 21]

The ceramic sintered body substrate according to any one of clauses 17 to 20, wherein the metal compound contains at least one element selected from Ti, Ce, Zr, and Mg.

### [Clause 22]

The ceramic sintered body substrate according to any one of clauses 17 to 21, wherein a median diameter of the metal powder is in a range from 1 μm to 50 μm.

### [Clause 23]

The ceramic sintered body substrate according to any one of clauses 17 to 22, wherein
the through hole has a circular shape when the ceramic substrate is cut horizontally, and
a diameter of the through hole is in a range from 0.05 mm to 0.5 mm.

### [Clause 24]

A light-emitting device comprising:
the ceramic sintered body substrate according to any one of clauses 17 to 23; and
a light-emitting element electrically connected to the first metal body of the ceramic sintered body substrate.

### INDUSTRIAL APPLICABILITY

A light-emitting device according to the embodiments of the present disclosure can be utilized for an adoptive driving beam headlamp. In addition, the light-emitting devices according to the embodiments of the present disclosure can be utilized for the light source for a backlight of a liquid crystal display, various types of lighting fixtures, a large display, various types of display devices for advertisements, destination information, and the like, and further, a digital video camera, image reading devices in a facsimile, a copy machine, a scanner, and the like, and a projector device, for example.

### REFERENCE SIGNS LIST

1 Ceramic substrate
2 Through hole
3 First metal paste
3a First metal body
4 First metal powder
4a Metal powder
4b Second metal
40b Covering metal member
50 Active metal powder
5 Metal compound
5a Reaction layer of metal compound
5b Reactant of metal compound
6 Organic binder
7 Inorganic filler
8 Conductive paste
8a Conductor
10 Ceramic sintered body substrate
11 Bonding member
12 Metal bump
20 Light-emitting element
21 Semiconductor layered body
22 Element substrate
23 Light-transmissive member
24 Element electrode
30 Light reflective member
100 Light-emitting device

1. A method for manufacturing a ceramic sintered body substrate, comprising:
preparing a ceramic substrate provided with a through hole before firing;
disposing a first metal paste in the through hole; and
firing the ceramic substrate provided with the first metal paste, wherein
in the disposing of the first metal paste, the first metal paste comprises,
a plurality of particles of first metal powder, and
a plurality of particles of active metal powder, and
the first metal powder comprises,
a metal powder serving as a core, and
a covering metal member having a melting point lower than a melting point of the metal powder and covering at least a part of the metal powder, and
in the firing of the ceramic substrate, a firing temperature is a temperature in a range from 700° C. to less than the melting point of the metal powder.

2. The method for manufacturing a ceramic sintered body substrate, according to claim 1, wherein in the disposing of the first metal paste, the metal powder contains at least one selected from Cu, Cr, and Ni.

3. The method for manufacturing a ceramic sintered body substrate, according to claim 1, wherein in the disposing of the first metal paste, the covering metal member contains at least one selected from Ag, Al, Zn, Sn, and an Ag—Cu alloy.

4. The method for manufacturing a ceramic sintered body substrate, according to claim 1, wherein in the disposing of the first metal paste, the covering metal member has a thickness in a range from 3% to 30% of a diameter or major axis of the metal powder.

5. The method for manufacturing a ceramic sintered body substrate, according to claim 1, wherein in the disposing of the first metal paste, a median diameter of the metal powder is in a range from 1 m to 50 km.

6. The method for manufacturing a ceramic sintered body substrate, according to claim 1, wherein in the disposing of the first metal paste, the active metal powder contains at least one selected from TiH₂, CeH₂, ZrH₂, and MgH₂.

7. The method for manufacturing a ceramic sintered body substrate, according to claim 1, wherein in the disposing of the first metal paste, the melting point of the metal powder is in a range from 1050° C. to 2500° C.

8. The method for manufacturing a ceramic sintered body substrate, according to claim 1, wherein in the disposing of the first metal paste, the melting point of the covering metal member is in a range from 200° C. to 1000° C.

9. The method for manufacturing a ceramic sintered body substrate, according to claim 1, wherein in the disposing of the first metal paste, the first metal paste further comprises an organic binder.

10. The method for manufacturing a ceramic sintered body substrate, according to claim 1, wherein in the disposing of the first metal paste, the first metal paste further comprises a plurality of particles of inorganic fillers other than a metal.

11. The method for manufacturing a ceramic sintered body substrate, according to claim 1, wherein in the firing of the ceramic substrate, the firing temperature is 1000° C. or less.

12. The method for manufacturing a ceramic sintered body substrate, according to claim 1, wherein in the firing of the ceramic substrate, the firing temperature is 950° C. or less.

13. The method for manufacturing a ceramic sintered body substrate, according to claim 1, wherein in the firing of the ceramic substrate, a firing atmosphere is an Ar atmosphere of 99.9% or more or a vacuum atmosphere of 10⁻⁵ Pa or less.

14. The method for manufacturing a ceramic sintered body substrate, according to claim 1, wherein, after the disposing of the first metal paste, disposing of a conductive paste on the ceramic substrate is performed such that the conductive paste is at least partially in contact with the first metal paste, before the firing of the ceramic substrate.

15. A method for manufacturing a light-emitting device, comprising:
preparing a ceramic sintered body substrate manufactured by the method for manufacturing a ceramic sintered body substrate according to any one of claims 1 to 13; and
disposing a light-emitting element on the ceramic sintered body substrate, wherein
in the preparing of the ceramic sintered body substrate, the first metal paste becomes a first metal body by firing, and
in the disposing of the light-emitting element, the first metal body disposed in the through hole is directly or indirectly electrically connected to the light-emitting element.

16. A method for manufacturing a light-emitting device, comprising:
preparing a ceramic sintered body substrate manufactured by the method for manufacturing a ceramic sintered body substrate according to claim 14; and
disposing a light-emitting element on the ceramic sintered body substrate, wherein
in the preparing of the ceramic sintered body substrate, the first metal paste becomes a first metal body and the conductive paste becomes a conductor, by firing, and
in the disposing of the light-emitting element, the first metal body disposed in the through hole or the conductor is directly or indirectly electrically connected to the light-emitting element.

17. A ceramic sintered body substrate comprising:
a ceramic substrate provided with a through hole; and
a first metal body disposed in the through hole, wherein
the first metal body comprises a plurality of particles of metal powder, a second metal, and a metal compound, the metal powder having a melting point higher than a melting point of the second metal and being dispersed in the second metal that is continuous, and
the ceramic substrate comprises a reaction layer of the metal compound on an inner wall of the through hole, and a reactant of the metal compound on a grain boundary of the metal powder.

18. The ceramic sintered body substrate according to claim 17, wherein the metal powder contains at least one selected from Cu, Cr, and Ni.

19. The ceramic sintered body substrate according to claim 17, wherein the second metal contains at least one selected from Ag, Al, Zn, Sn, and an Ag—Cu alloy.

20. The ceramic sintered body substrate according to claim 17, wherein the ceramic substrate contains at least one selected from silicon nitride, aluminum nitride, and boron nitride.

21. The ceramic sintered body substrate according to claim 17, wherein the metal compound contains at least one element selected from Ti, Ce, Zr, and Mg.

22. The ceramic sintered body substrate according to claim 17, wherein a median diameter of the metal powder is in a range from 1 m to 50 km.

23. The ceramic sintered body substrate according to claim 17, wherein
the through hole has a circular shape when the ceramic substrate is cut horizontally, and
a diameter of the through hole is in a range from 0.05 mm to 0.5 mm.

24. A light-emitting device comprising:
the ceramic sintered body substrate according to any one of claims 17 to 23; and
a light-emitting element electrically connected to the first metal body of the ceramic sintered body substrate.
